(19) United States
(12) Patent Application Publication
(10) Pub. No.: US 2025/0324796 A1
(43) Pub. Date: Oct. 16, 2025

(54) IMAGE SENSOR

(71) Applicant: VisEra Technologies Company Limited, Hsin-Chu City (TW)

(72) Inventors: Shin-Hong KUO, Hsin-Chu City (TW); Kai-Hao CHANG, Hsin-Chu City (TW); Po-Hsiang WANG, Hsin-Chu City (TW)

(21) Appl. No.: 18/633,991

(22) Filed: Apr. 12, 2024

(51) Int. Cl. H01L 27/146

(52) U.S. Cl. CPC H10F 39/8063; H10F 39/182

(57) ABSTRACT

An image sensor includes a meta-surface layer. The meta-surface layer includes a plurality of meta-pillars. The image sensor further includes an optical functional layer on the meta-surface layer and covering the meta-surface layer. In a pixel region, each of the meta-pillars of the meta-surface layer corresponds to at least one opening in the optical functional layer or to a plurality of optical functional pillars in the optical functional layer.

### BACKGROUND OF THE INVENTION

### Field of the Invention

The present disclosure relates to an image sensor, and in particular to an image sensor with an optical functional layer covering the meta-surface layers.

### Description of the Related Art

Image sensors, such as complementary metal oxide semiconductor (CMOS) image sensors (also known as CIS), are widely used in various image-capturing apparatuses such as digital still-image cameras, digital video cameras, and the like. The light-sensing portion of the image sensor may detect ambient color change, and signal electric charges may be generated depending on the amount of light received in the light-sensing portion. In addition, the signal electric charges generated in the light-sensing portion may be transmitted and amplified to obtain an image signal.

Recently, meta-surfaces have garnered significant attention in the field of optics. For example, meta-surfaces may be used in conjunction with image sensors (such as a CMOS image sensor). These meta-surfaces are capable of manipulating the properties of electromagnetic waves (e.g. an incident wave). For example, these meta-surfaces may be used as lenses, polarizers, beam-shaping devices, and tunable phase modulators. Also, these meta-surfaces may be designed to correct aberrations such as spherical aberrations and chromatic aberrations. Image quality may thereby be enhanced.

However, existing meta-surfaces have not been satisfactory in all respects. In order for the finished product to maintain a high level of performance, the industry still needs to improve these meta-surfaces to achieve their goal of maintaining the yield of image sensors.

### BRIEF SUMMARY OF THE INVENTION

An embodiment of the present disclosure provides an image sensor that includes a meta-surface layer. The meta-surface layer includes a plurality of meta-pillars. The image sensor further includes an optical functional layer on the meta-surface layer and covering the meta-surface layer. In a pixel region, each of the meta-pillars in the meta-surface layer corresponds to at least one opening in the optical functional layer or to a plurality of optical functional pillars in the optical functional layer.

### BRIEF DESCRIPTION OF THE DRAWINGS

Aspects of the present disclosure are best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion.

FIG. 1 illustrates a perspective view of the image sensor according to some embodiments of the present disclosure;

FIGS. 2A, 2B, 2C, 2D, and 2E illustrate fragmentary top views of the image sensor according to some embodiments of the present disclosure;

FIG. 3 illustrates a perspective view of the image sensor according to some embodiments of the present disclosure;

FIGS. 4A, 4B, 4C, 4D, and 4E illustrate fragmentary perspective views at the top of the image sensor according to some embodiments of the present disclosure;

FIG. 5 illustrates a perspective view of the image sensor according to some embodiments of the present disclosure;

FIGS. 6A, 6B, 6C, 6D, 6E, 6F, 6G, and 6H illustrate fragmentary top views of the image sensor according to some embodiments of the present disclosure;

FIGS. 7A, 7B, 7C, 7D, and 7E illustrate fragmentary perspective views at the top of the image sensor according to some embodiments of the present disclosure;

FIG. 8 illustrates a perspective view of the image sensor according to some embodiments of the present disclosure;

FIGS. 9A, 9B, and 9C illustrate cross-sectional views of the image sensor according to some embodiments of the present disclosure;

FIG. 10 illustrates a perspective view of the image sensor according to some embodiments of the present disclosure;

FIG. 11 illustrates a cross-sectional view of the image sensor according to some embodiments of the present disclosure; and

FIG. 12 illustrates a cross-sectional view of the image sensor according to some embodiments of the present disclosure.

### DETAILED DESCRIPTION OF THE INVENTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Further, when a number or a range of numbers is described with “about,” “approximate,” and the like, the term is intended to encompass numbers that are within a reasonable range considering variations that inherently arise during the manufacturing process, as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer with a thickness of “about 5 nm” can encompass a dimension range from 4.25 nm to 5.75 nm where manufacturing tolerances associated with depositing the material layer are known to be +/−15% by one of ordinary skill in the art.

Unless otherwise defined, all terms (including technical and scientific terms) used herein have the same meaning as commonly understood by one of ordinary skill in the art to which this disclosure belongs. It should be understood that terms such as those defined in commonly used dictionaries should be interpreted as having a meaning that is consistent with their meaning in the context of the prior art and will not be interpreted in an idealized or overly formal sense unless expressly so defined in the embodiments of the present disclosure.

The present disclosure may repeat reference numerals and/or letters in following embodiments. This repetition is for the purpose of simplicity and clarity and does not in itself dictate a relationship between the various embodiments and/or configurations discussed.

Generally, the meta-surface layer may provide several optical functionalities, such as phase correction and aberration correction, and the light-collecting efficiency may be enhanced and the possibility of image distortion may be effectively reduced. When the meta-surface layer is used as the phase corrector, the phase of the incident wave may be modulated. When the meta-surface layer is used as the aberration corrector, the performance of the image sensor and/or the image quality may be improved. In conventional configurations, the image sensor with the meta-surface layer generally requires an additional conformal refractive index matching layer to minimize the light reflection from the top surface of the meta-pillars in the meta-surface layer. More specifically, while the meta-surface layer may be used as a lens, router, or color filter, the high refractive index of the material of the meta-surface layer may result in high reflectivity at the top surface of the meta-pillars, and thus a conformal refractive index matching layer is needed to minimize its reflection. The embodiment of the present disclosure provides a novel optical function layer that replaces the conformal refractive index matching layer and covers the meta-surface layer, which reduces the interface reflectivity, improves the efficiency of light transmission, and reduces high reflection problems (e.g., flares) in the image sensor.

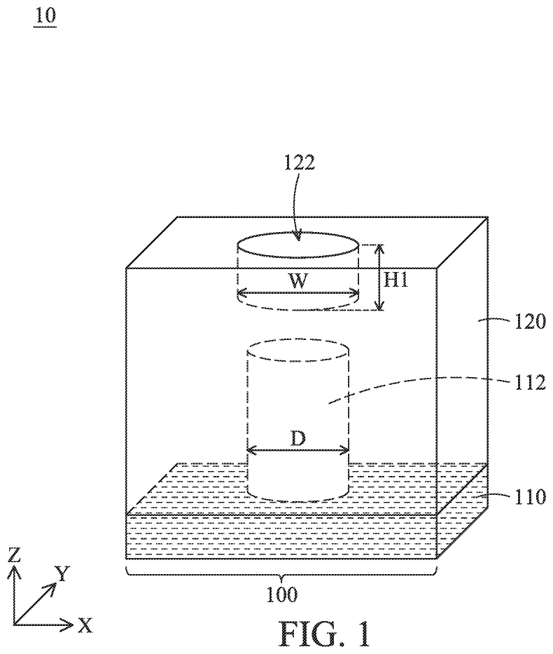

FIG. 1 illustrates a perspective view of the image sensor 10 according to some embodiments of the present disclosure. In some embodiments, the image sensor 10 includes a meta-surface layer 110 and an optical functional layer 120 in a pixel region 100. In some embodiments, the meta-surface layer 110 includes a plurality of meta-pillars 112. For the sake of simplicity, only one meta-pillar 112 is shown in FIG. 1. In some embodiments, the optical functional layer 120 is disposed on the meta-surface layer 110 and covering the meta-surface layer 110. The optical functional layer 120 may increase the energy efficiency, and may improve the light transmittance and the contrast of the image sensor 10. In the embodiments of the present disclosure, in the pixel region 100, each of the meta-pillars 112 in the meta-surface layer 110 corresponds to at least one opening 122 in the optical functional layer 120 or to a plurality of optical functional pillars 124 in the optical functional layer 120. More specifically, in some embodiments, as shown in FIG. 1, each of the meta-pillars 112 in the meta-surface layer 110 corresponds to one opening 122 in the optical functional layer 120 in the pixel region 100. By utilizing the opening 122 in the optical functional layer 120, the reflection issue that may occur on the top surface of the meta-pillars 112 in the meta-surface layer 110 may be improved. In some embodiments, the openings 122 are recessed from the top of the optical functional layer 120. In some embodiments, the width W of the openings 122 satisfies the relationship 3·D>W>0.25·D, wherein D is the diameter of each of the meta-pillars 112 in the meta-surface layer 110. In some embodiments, the height H1 of the openings 122 satisfies the relationship 3 μm>H1>0.2 μm. In some embodiments, examples of the material of the meta-surface layer 110 may include a dielectric material, a metal material, and the like. For example, the meta-surface layer 110 may be made of carbon nanotubes (CNTs), two-dimensional transition metal dichalcogenides (2D TMDs), SiC, ZrO₂, TiOₓ, SiNₓ, Indium Tin Oxides (ITO), Si, amorphous Si (a-Si), polycrystalline Si (p-Si), a III-V semiconductor compound, or a combination thereof. In some embodiments, the refractive index of the meta-surface layer 110 is about 1.6 to 2.6.

Still referring to FIG. 1, in some embodiments, the optical functional layer 120 connects the openings 122 and each of the meta-pillars 112 in the meta-surface layer 110. In other words, the openings 122 and each of the meta-pillars 112 in the meta-surface layer 110 do not contact each other. In some embodiments, the distance between the openings 122 and each of the meta-pillars 112 in the meta-surface layer 110 is within a range of about 10 nm to about 50 μm. Depending on the design requirements, the openings 122 may help to stabilize the phase of the light if the distance is relatively large, or may rearrange the light distribution with each of the meta-pillars 112 in the meta-surface layer 110 if the distance is relatively small. In some embodiments, the material of the optical functional layer 120 includes an acrylic, a photoresist, ZrO₂, TiO₂, SiN, Indium Tin Oxide (ITO), Si, amorphous Si (a-Si), polycrystalline silicon (p-Si), a III-V semiconductor compound, or a combination thereof.

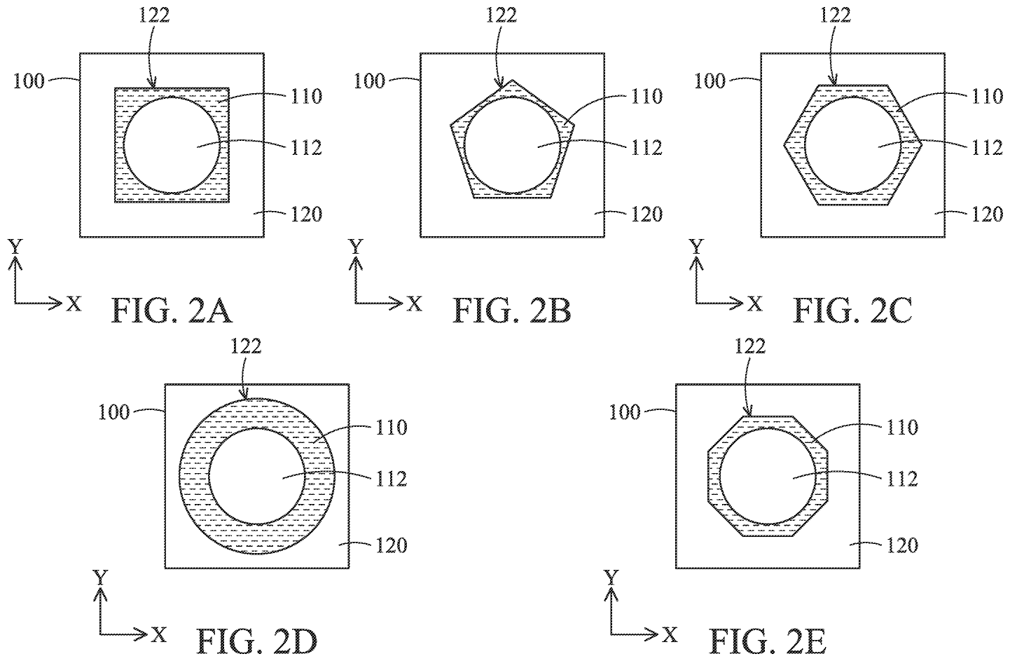

Refer to FIGS. 2A, 2B, 2C, 2D, and 2E, and in conjunction with FIG. 1. FIGS. 2A, 2B, 2C, 2D, and 2E illustrate fragmentary top views of the image sensor 10 according to some embodiments of the present disclosure. In other words, FIGS. 2A, 2B, 2C, 2D, and 2E illustrate the pixel region 100 and the shape of the openings 122 in the top views when each of the meta-pillars 112 in the meta-surface layer 110 corresponds to one opening 122. In some embodiments, as shown in FIG. 2A, in the top view, the openings 122 include a rectangular shape. In some embodiments, as shown in FIG. 2B, in the top view, the openings 122 have a pentagonal shape. In some embodiments, as shown in FIG. 2C, in the top view, the openings 122 have a hexagonal shape. In some embodiments, as shown in FIG. 2D, in the top view, the openings 122 have a round shape. In some embodiments, as shown in FIG. 2E, in the top view, the openings 122 have a polygonal shape, such as an octagon. In some embodiments, each of the meta-pillars 112 in the meta-surface layer 110 is concentric with the opening 122 when there is only one opening 122, as shown in FIGS. 2A, 2B, 2C, 2D, and 2E.

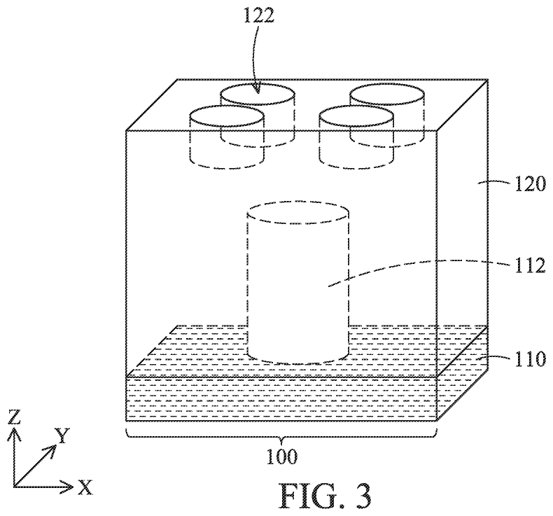

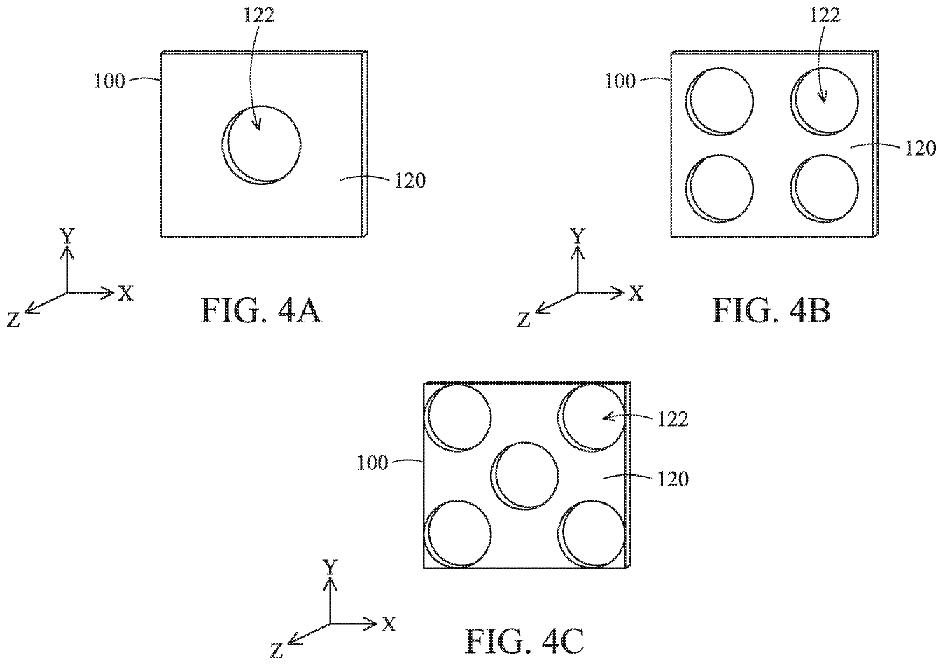

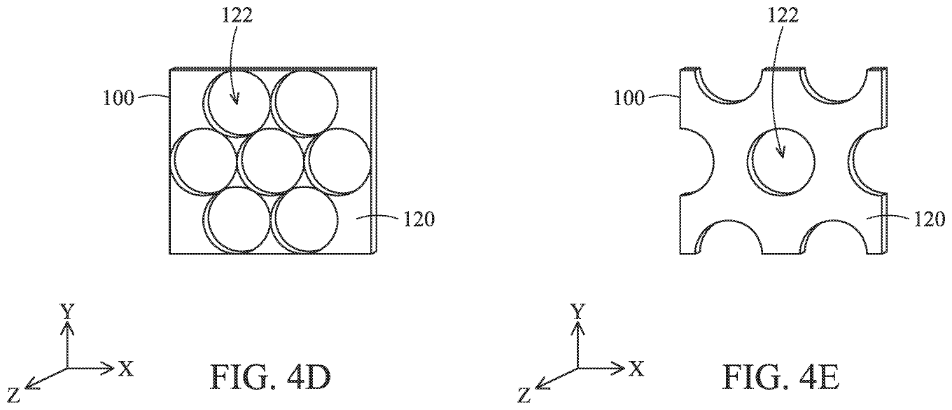

Refer to FIG. 3, and in conjunction with FIGS. 4A, 4B, 4C, 4D, and 4E. FIG. 3 illustrates a perspective view of the image sensor 10 according to some embodiments of the present disclosure. FIGS. 4A, 4B, 4C, 4D, and 4E illustrate fragmentary perspective views at the top of the image sensor 10 according to some embodiments of the present disclosure. In some embodiments, as shown in FIG. 3, each of the meta-pillars 112 in the meta-surface layer 110 may correspond to four openings 122 in the optical functional layer 120 in the pixel region 100. In some embodiments, each of the meta-pillars 112 in the meta-surface layer 110 may correspond to 1, 4, 5, or 7 openings 122 in the optical functional layer 120 in the pixel region 100. It should be noted that the number of openings 122 mentioned herein is only an example, and is not intended to limit the present disclosure. More specifically, in some embodiments, FIG. 4A illustrates a perspective view at the top of the optical functional layer 120 in the pixel region 100, where each of the meta-pillars 112 in the meta-surface layer 110 corresponds to one opening 122. In some embodiments, FIG. 4B illustrates a perspective view at the top of the optical functional layer 120 in the pixel region 100, where each of the meta-pillars 112 in the meta-surface layer 110 corresponds to four openings 122. In some embodiments, FIG. 4C illustrates a perspective view at the top of the optical functional layer 120 in the pixel region 100, where each of the meta-pillars 112 in the meta-surface layer 110 corresponds to five openings 122. In some embodiments, FIGS. 4D and 4E illustrate the perspective views at the top of the optical functional layer 120 in the pixel region 100, where each of the meta-pillars 112 in the meta-surface layer 110 corresponds to seven openings 122. In some embodiments, as shown in FIGS. 4A, 4B, 4C, and 4D, the openings 122 are arranged in a polygonal arrangement. In some embodiments, as shown in FIG. 4E, the openings 122 are arranged in an irregular arrangement.

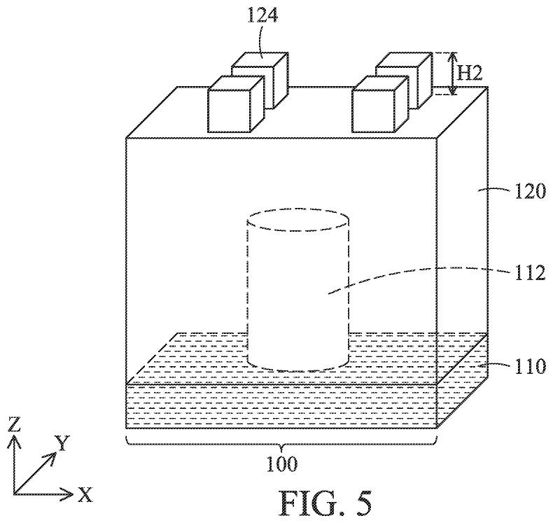

Referring to FIG. 5, FIG. 5 illustrates a perspective view of the image sensor 10 according to some embodiments of the present disclosure. In the embodiments of the present disclosure, in the pixel region 100, each of the meta-pillars 112 in the meta-surface layer 110 corresponds to at least one opening 122 in the optical functional layer 120 or to a plurality of optical functional pillars 124 in the optical functional layer 120. More specifically, in some embodiments, as shown in FIG. 5, each of the meta-pillars 112 in the meta-surface layer 110 corresponds to four optical functional pillars 124 in the optical functional layer 120 in the pixel region 100. By utilizing the optical functional pillars 124 in the optical functional layer 120, the reflection issue that may occur on the top surface of the meta-pillars 112 in the meta-surface layer 110 may be improved. In some embodiments, the optical functional pillars 124 protrude from the top of the optical functional layer 120. In some embodiments, the height H2 of each of the optical functional pillars 124 in the optical functional layer 120 satisfies the relationship 3 μm>H2>0.2 μm. In some embodiments, the material of the optical functional pillars 124 includes an acrylic, a photoresist, ZrO₂, TiO₂, SiN, Indium Tin Oxide (ITO), Si, amorphous Si (a-Si), polycrystalline silicon (p-Si), a III-V semiconductor compound, or a combination thereof.

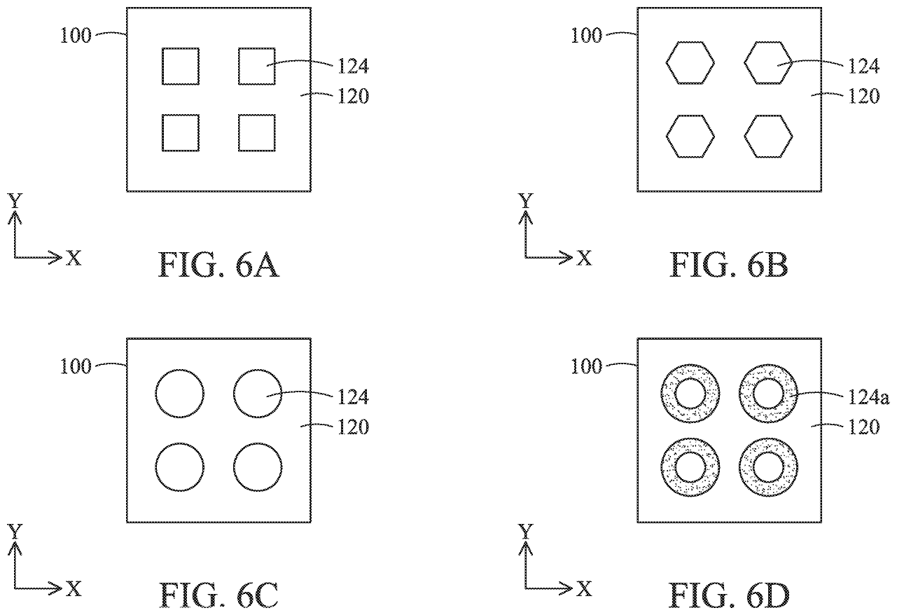

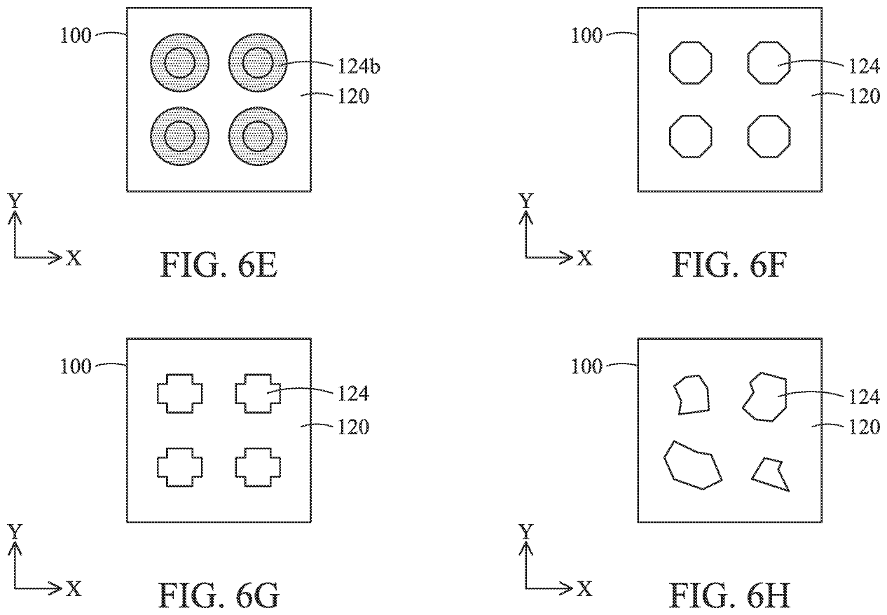

FIGS. 6A, 6B, 6C, 6D, 6E, 6F, 6G, and 6H illustrate fragmentary top views of the image sensor 10 according to some embodiments of the present disclosure. In some embodiments, in the top views, the optical functional pillars 124 in the optical functional layer 120 have a rectangular shape, a hexagonal shape, a round shape, a ring shape, a concentric circle shape, a polygonal shape, a cross shape, or an irregular shape. More specifically, in some embodiments, as shown in FIG. 6A, in the top view, the optical functional pillars 124 in the optical functional layer 120 in the pixel region 100 have a rectangular shape. In some embodiments, as shown in FIG. 6B, in the top view, the optical functional pillars 124 in the optical functional layer 120 in the pixel region 100 have a hexagonal shape. In some embodiments, as shown in FIG. 6C, in the top view, the optical functional pillars 124 in the optical functional layer 120 in the pixel region 100 have a round shape. In some embodiments, as shown in FIG. 6D, in the top view, the optical functional pillars 124a in the optical functional layer 120 in the pixel region 100 have a ring shape. In some embodiments, as shown in FIG. 6E, in the top view, the optical functional pillars 124b in the optical functional layer 120 in the pixel region 100 have a concentric circle shape. In some embodiments, as shown in FIG. 6F, in the top view, the optical functional pillars 124 in the optical functional layer 120 in the pixel region 100 have a polygonal shape, such as an octagon. In some embodiments, as shown in FIG. 6G, in the top view, the optical functional pillars 124 in the optical functional layer 120 in the pixel region 100 have a cross shape. In some embodiments, as shown in FIG. 6H, in the top view, the optical functional pillars 124 in the optical functional layer 120 in the pixel region 100 have an irregular shape.

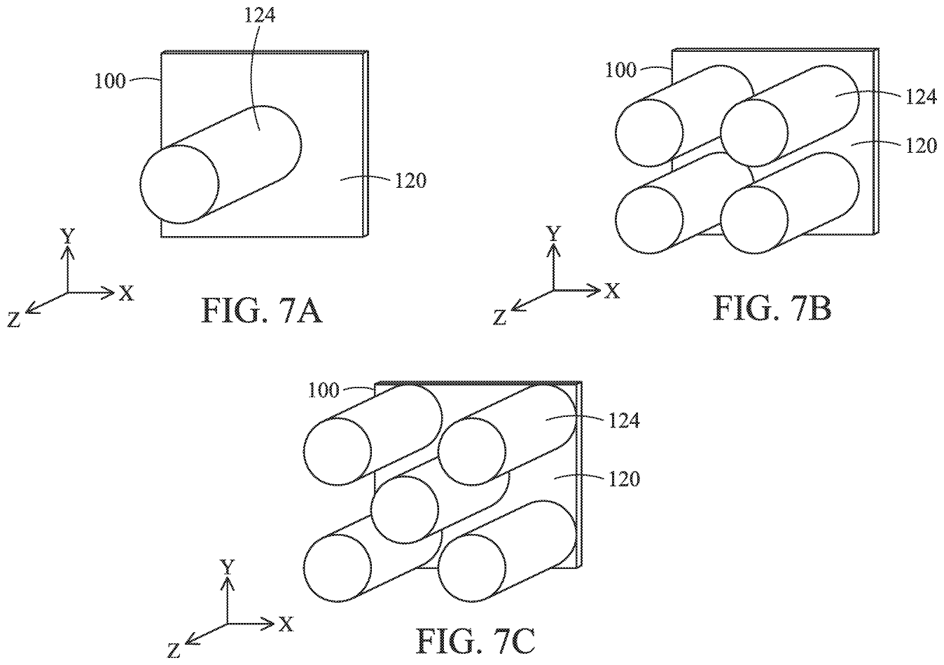

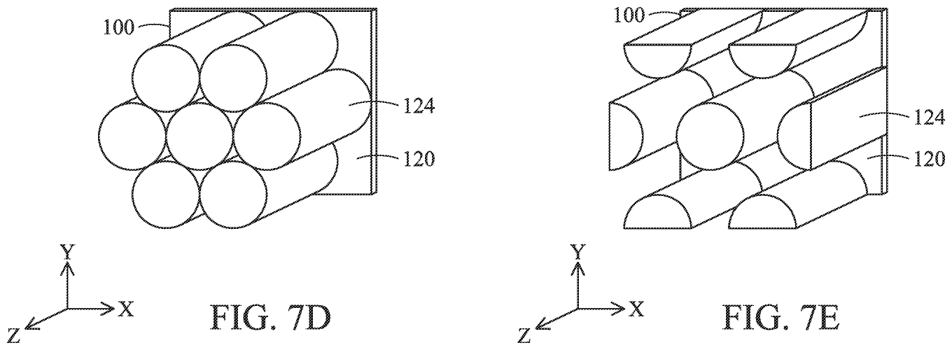

Refer to FIGS. 7A, 7B, 7C, 7D, and 7E, and in conjunction with FIG. 5. FIGS. 7A, 7B, 7C, 7D, and 7E illustrate fragmentary perspective views at the top of the image sensor 10 according to some embodiments of the present disclosure. In some embodiments, as shown in FIG. 5, each of the meta-pillars 112 in the meta-surface layer 110 corresponds to four optical functional pillars 124 in the optical functional layer 120 in the pixel region 100. In some embodiments, the number of optical functional pillars 124 in the optical functional layer 120 in the pixel region 100 may be 1, 4, 5, or 7. It should be noted that the number of optical functional pillars 124 mentioned herein is only an example, and is not intended to limit the present disclosure. More specifically, in some embodiments, FIG. 7A illustrates a perspective view at the top of the optical functional layer 120 in the pixel region 100, where each of the meta-pillars 112 in the meta-surface layer 110 corresponds to one optical functional pillar 124. In some embodiments, FIG. 7B illustrates a perspective view at the top of the optical functional layer 120 in the pixel region 100, where each of the meta-pillars 112 in the meta-surface layer 110 corresponds to four optical functional pillars 124. In some embodiments, FIG. 7C illustrates a perspective view at the top of the optical functional layer 120 in the pixel region 100, where each of the meta-pillars 112 in the meta-surface layer 110 corresponds to five optical functional pillars 124. In some embodiments, FIGS. 7D and 7E illustrate the perspective views at the top of the optical functional layer 120 in the pixel region 100, where each of the meta-pillars 112 in the meta-surface layer 110 corresponds to seven optical functional pillars 124. In some embodiments, as shown in FIGS. 7A, 7B, 7C, and 7D, the optical functional pillars 124 are arranged in a polygonal arrangement. In some embodiments, as shown in FIG. 7E, the optical functional pillars 124 are arranged in an irregular arrangement.

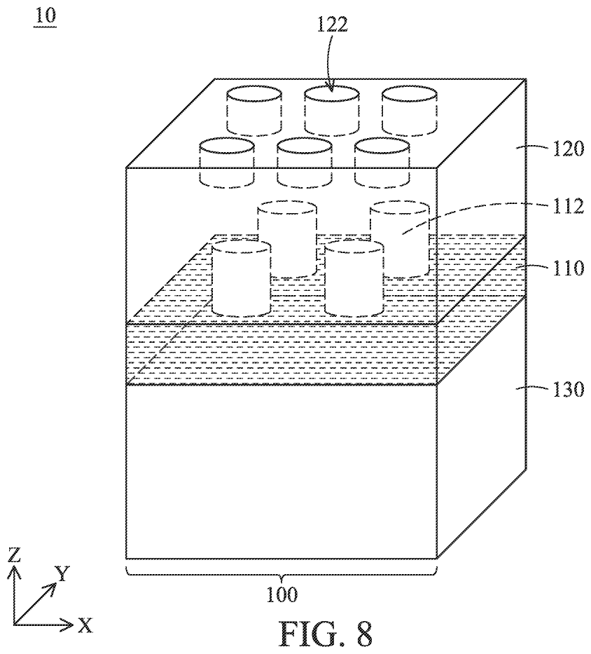

FIG. 8 illustrates a perspective view of the image sensor 10 according to some embodiments of the present disclosure. In some embodiments, the image sensor 10 further includes an absorption layer 130 below the meta-surface layer 110. The absorption layer 130 may reduce other wavelengths passing through the image sensor 10. In some embodiments, the absorption layer 130 includes an infrared (IR)-cut material or an ultraviolet (UV)-cut material. In some embodiments, the IR-cut material may absorb the wavelengths between about 750 nm to about 1200 nm. In some embodiments, the UV-cut material may absorb the wavelengths less than 350 nm. In some embodiments, the absorption layer 130 is a multi-film structure.

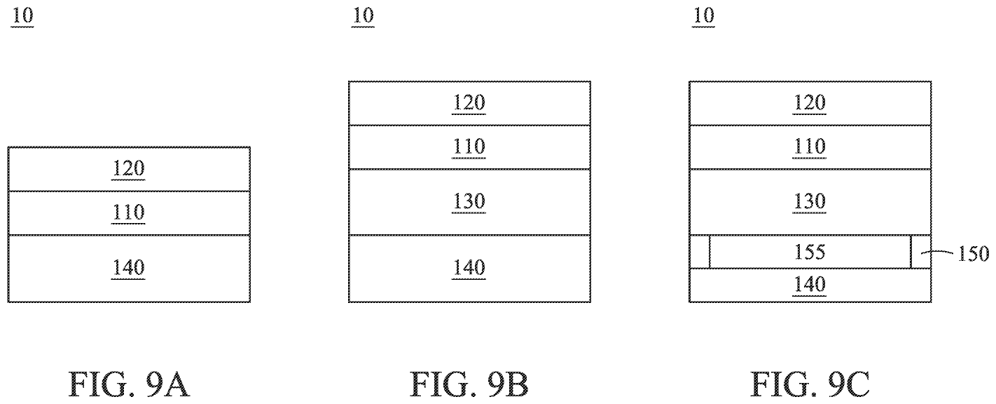

FIGS. 9A, 9B, and 9C illustrate cross-sectional views of the image sensor 10 according to some embodiments of the present disclosure. In some embodiments, the image sensor 10 further includes a sensor layer 140 below the meta-surface layer 110. In other words, the meta-surface layer 110 and the optical functional layer 120 are formed over the sensor layer 140. In some embodiments, the sensor layer 140 may form on a substrate (not shown). In some embodiments, the substrate may be an elemental semiconductor including silicon or germanium; a compound semiconductor including gallium nitride (GaN), silicon carbide (SiC), gallium arsenide (GaAs), gallium phosphide (GaP), indium phosphide (InP), indium arsenide (InAs), and/or indium antimonide (InSb); an alloy semiconductor including silicon germanium (SiGe) alloy, gallium arsenide phosphide (GaAsP) alloy, aluminum indium arsenide (AlInAs) alloy, aluminum gallium arsenide (AlGaAs) alloy, gallium indium arsenide (GaInAs) alloy, gallium indium phosphide (GalnP) alloy, and/or gallium indium arsenide phosphide (GalnAsP) alloy; or a combination thereof. In some embodiments, the substrate may be a photoelectric conversion substrate, for example, silicon substrate or organic photoelectric conversion layer. In other embodiments, the substrate may also be a semiconductor on insulator (SOI) substrate. The semiconductor on insulator substrate may include a base plate, a buried oxide layer disposed on the base plate, and a semiconductor layer disposed on the buried oxide layer. Furthermore, the substrate may be an N-type or a P-type conductive type.

Still refer to FIGS. 9A, 9B, and 9C. In some embodiments, as shown in FIG. 9A, the meta-surface layer 110 and the optical functional layer 120 are formed on the sensor layer 140. In some embodiments, as shown in FIG. 9B, the absorption layer 130 is formed on the sensor layer 140, and the meta-surface layer 110 and the optical functional layer 120 are formed on the absorption layer 130. That is, as shown in FIG. 9B, the absorption layer 130 is between the sensor layer 140 and the meta-surface layer 110. In some embodiments, as shown in FIG. 9C, a supporting structure 150 is formed on the sensor layer 140, the absorption layer 130 is formed on the supporting structure 150, and the meta-surface layer 110 and the optical functional layer 120 are formed on the absorption layer 130. That is, as shown in FIG. 9C, the absorption layer 130 is between the supporting structure 150 and the meta-surface layer 110. In some embodiments, as shown in FIG. 9C, the supporting structure 150 includes an air gap 155, and the absorption layer 130 and the sensor layer 140 are separated by the air gap 155.

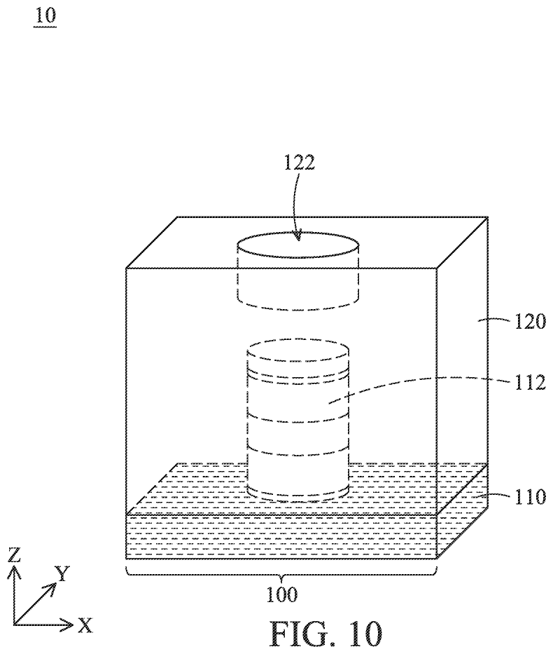

FIG. 10 illustrates a perspective view of the image sensor 10 according to some embodiments of the present disclosure. In some embodiments, in the pixel region 100, each of the meta-pillars 112 in the meta-surface layer 110 is a multi-film structure with metallic or transparent conducting materials. Using the multi-film structure may further improve the performance of the image sensor 10 and/or the image quality.

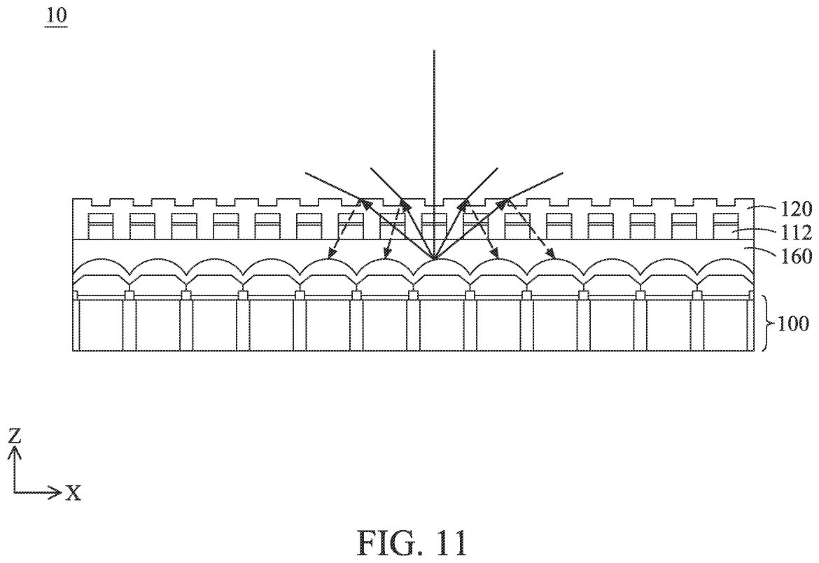

Refer to FIG. 11, and in conjunction with FIG. 9A. FIG. 11 illustrates a cross-sectional view of the image sensor 10 according to some embodiments of the present disclosure. In some embodiments, the image sensor 10 includes the sensor layer 140 below the meta-surface layer 110. In some embodiments, the meta-surface layer 110 and the optical functional layer 120 are formed on the sensor layer 140. In addition, as shown in FIG. 11, the image sensor 10 further includes a buffer layer 160 between the sensor layer 140 and the meta-surface layer 110. The meta-surface layer 110 and the optical functional layer 120 are disposed closer to the sensor layer 140, which may reduce the petal flare region and provide a better angular response to the light.

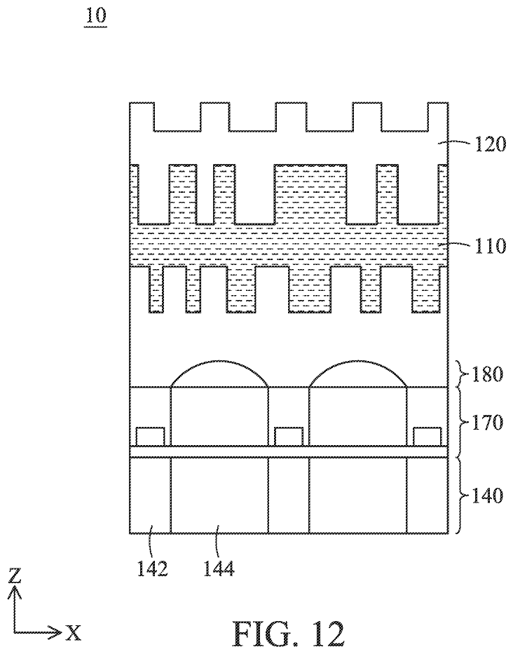

FIG. 12 illustrates a cross-sectional view of the image sensor 10 according to some embodiments of the present disclosure. In some embodiments, the image sensor 10 includes the sensor layer 140 below the meta-surface layer 110. In some embodiments, a color filter layer 170 is disposed on the sensor layer 140. In some embodiments, a micro lens layer 180 is disposed on the color filter layer 170. In some embodiments, the color filter layer 170 and the micro lens layer 180 are between the sensor layer 140 and the meta-surface layer 110. In some embodiments, the sensor layer 140 may include a light-shielding layer 142 and a sensor component 144. The light-shielding layer 142 may define the region of the sensor component 144. The sensor component 144 may include sensing unit, such as photodiodes, which may convert received light signals into electric signals. In some embodiments, the light-shielding layer 142 may have a lower refractive index than the sensor component 144. The refractive index is a characteristic of a substance that changes the speed of light, and is a value obtained by dividing the speed of light in vacuum by the speed of light in the substance. When light travels between two different materials at an angle, its refractive index determines the angle of light transmission (refraction). When incident light enters the sensor layer 140, the light-shielding layer 142 may isolate light rays within the specific unit to serve as the light-trapping function. In some embodiments, the material of the light-shielding layer 142 may include a transparent dielectric material.

In summary, the embodiment of the present disclosure provides a novel optical function layer that replaces the conformal refractive index matching layer and covers the meta-surface layer, which reduces the interface reflectivity, improves the efficiency of light transmission, and reduces high reflection problems (e.g., flares) in the image sensor. Thus, the various embodiments described herein offer several advantages over the existing art. It will be understood that not all advantages have been necessarily discussed herein, no particular advantage is required for all embodiments, and other embodiments may offer different advantages.

The embodiments of the present disclosure provides an image sensor, including a meta-surface layer. The meta-surface layer includes a plurality of meta-pillars. The image sensor further includes an optical functional layer on the meta-surface layer and covering the meta-surface layer. In a pixel region, each of the meta-pillars in the meta-surface layer corresponds to at least one opening in the optical functional layer or to a plurality of optical functional pillars in the optical functional layer.

In some embodiments, the width W of the openings satisfies the relationship 3·D>W>0.25·D, wherein D is the diameter of each of the meta-pillars in the meta-surface layer. In some embodiments, the height H1 of the openings satisfies the relationship 3 μm>H1>0.2 μm. In some embodiments, in a top view, the openings have a rectangular shape, a pentagonal shape, a hexagonal shape, a round shape, or a polygonal shape. In some embodiments, the optical functional layer connects the openings and each of the meta-pillars in the meta-surface layer.

In some embodiments, in the pixel region, each of the meta-pillars in the meta-surface layer corresponds to 1, 4, 5, or 7 openings in the optical functional layer. In some embodiments, the openings are arranged in a polygonal arrangement or an irregular arrangement. In some embodiments, in a top view, the optical functional pillars in the optical functional layer have a rectangular shape, a hexagonal shape, a round shape, a ring shape, a concentric circle shape, a polygonal shape, a cross shape, or an irregular shape. In some embodiments, the material of the optical functional layer comprises an acrylic, a photoresist, ZrO₂, TiO₂, SiN, Indium Tin Oxide (ITO), Si, amorphous Si (a-Si), polycrystalline silicon (p-Si), a III-V semiconductor compound, or a combination thereof.

In some embodiments, the image sensor further includes an absorption layer below the meta-surface layer. In some embodiments, the absorption layer comprises an infrared (IR)-cut material or an ultraviolet (UV)-cut material. In some embodiments, the absorption layer is a multi-film structure.

In some embodiments, the image sensor further includes a sensor layer below the meta-surface layer, a supporting structure on the sensor layer, and an absorption layer between the supporting structure and the meta-surface layer. In some embodiments, the supporting structure comprises an air gap. In some embodiments, the absorption layer and the sensor layer are separated by the air gap.

In some embodiments, each of the meta-pillars in the meta-surface layer is a multi-film structure with metallic or transparent conducting materials. In some embodiments, the image sensor further includes a sensor layer below the meta-surface layer and a buffer layer between the sensor layer and the meta-surface layer. In some embodiments, the openings are recessed from the top of the optical functional layer. In some embodiments, each of the meta-pillars in the meta-surface layer is concentric with the opening when there is just one opening.

In some embodiments, the image sensor further includes a sensor layer below the meta-surface layer, a color filter layer on the sensor layer, and a micro lens layer on the color filter layer. In some embodiments, the color filter layer and the micro lens layer are between the sensor layer and the meta-surface layer. In some embodiments, in the pixel region, the number of optical functional pillars in the optical functional layer is 1, 4, 5, or 7. In some embodiments, the optical functional pillars in the optical functional layer are arranged in a polygonal arrangement or an irregular arrangement. In some embodiments, the height H2 of each of the optical functional pillars in the optical functional layer satisfies the relationship 3 μm>H2>0.2 μm.

The scope of the present disclosure is not limited to the technical solutions consisting of specific combinations of the technical features described above, but should also cover other technical solutions consisting of any combinations of the technical features described above or their equivalent features, all of which are within the scope of the protection of the present disclosure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure. Therefore, the scope of protection should be determined through the claims. In addition, although some embodiments of the present disclosure are disclosed above, they are not intended to limit the scope of the present disclosure.

Reference throughout this specification to features, advantages, or similar language does not imply that all of the features and advantages that may be realized with the present disclosure should be or are in any single embodiment of the disclosure. Rather, language referring to the features and advantages is understood to mean that a specific feature, advantage, or characteristic described in connection with an embodiment is included in at least one embodiment of the present disclosure. Thus, discussions of the features and advantages, and similar language, throughout this specification may, but do not necessarily, refer to the same embodiment.

Furthermore, the described features, advantages, and characteristics of the disclosure may be combined in any suitable manner in one or more embodiments. One skilled in the prior art will recognize, in light of the description herein, that the disclosure can be practiced without one or more of the specific features or advantages of a particular embodiment. In other instances, additional features and advantages may be recognized in certain embodiments that may not be present in all embodiments of the disclosure.

What is claimed is:

1. An image sensor, comprising:
a meta-surface layer, wherein the meta-surface layer comprises a plurality of meta-pillars; and
an optical functional layer on the meta-surface layer and covering the meta-surface layer,
wherein in a pixel region, each of the meta-pillars of the meta-surface layer corresponds to at least one opening in the optical functional layer or to a plurality of optical functional pillars in the optical functional layer.

2. The image sensor as claimed in claim 1, wherein a width W of the at least one opening satisfies 3·D>W>0.25·D, wherein D is a diameter of each of the meta-pillars of the meta-surface layer.

3. The image sensor as claimed in claim 1, wherein a height H1 of the at least one opening satisfies 3 μm>H1>0.2 μm.

4. The image sensor as claimed in claim 1, wherein in a top view, the at least one opening comprises a rectangular shape, a pentagonal shape, a hexagonal shape, a round shape, or a polygonal shape.

5. The image sensor as claimed in claim 1, wherein the optical functional layer connects the at least one opening and each of the meta-pillars of the meta-surface layer.

6. The image sensor as claimed in claim 1, wherein in the pixel region, each of the meta-pillars of the meta-surface layer corresponds to 1, 4, 5, or 7 openings in the optical functional layer.

7. The image sensor as claimed in claim 6, wherein the at least one opening is arranged in a polygonal arrangement or an irregular arrangement.

8. The image sensor as claimed in claim 1, wherein in a top view, the optical functional pillars in the optical functional layer comprise a rectangular shape, a hexagonal shape, a round shape, a ring shape, a concentric circle shape, a polygonal shape, a cross shape, or an irregular shape.

9. The image sensor as claimed in claim 1, wherein a material of the optical functional layer comprises an acrylic, a photoresist, ZrO₂, TiO₂, SiN, Indium Tin Oxide (ITO), Si, amorphous Si (a-Si), polycrystalline silicon (p-Si), a III-V semiconductor compound, or a combination thereof.

10. The image sensor as claimed in claim 1, further comprising:
an absorption layer below the meta-surface layer,
wherein the absorption layer comprises an infrared (IR)-cut material or an ultraviolet (UV)-cut material.

11. The image sensor as claimed in claim 10, wherein the absorption layer is a multi-film structure.

12. The image sensor as claimed in claim 1, further comprising:
a sensor layer below the meta-surface layer;
a supporting structure on the sensor layer; and
an absorption layer between the supporting structure and the meta-surface layer,
wherein the supporting structure comprises an air gap,
wherein the absorption layer and the sensor layer are separated by the air gap.

13. The image sensor as claimed in claim 1, wherein each of the meta-pillars of the meta-surface layer is a multi-film structure with metallic or transparent conducting materials.

14. The image sensor as claimed in claim 1, further comprising:
a sensor layer below the meta-surface layer; and
a buffer layer between the sensor layer and the meta-surface layer.

15. The image sensor as claimed in claim 1, wherein the at least one opening is recessed from a top of the optical functional layer.

16. The image sensor as claimed in claim 1, wherein each of the meta-pillars of the meta-surface layer is concentric with the at least one opening when the meta-pillars correspond to only one of the at least one opening.

17. The image sensor as claimed in claim 1, further comprising:
a sensor layer below the meta-surface layer;
a color filter layer on the sensor layer; and
a micro lens layer on the color filter layer,
wherein the color filter layer and the micro lens layer are between the sensor layer and the meta-surface layer.

18. The image sensor as claimed in claim 1, wherein in the pixel region, a number of the optical functional pillars in the optical functional layer is 1, 4, 5, or 7.

19. The image sensor as claimed in claim 18, wherein the optical functional pillars in the optical functional layer are arranged in a polygonal arrangement or an irregular arrangement.

20. The image sensor as claimed in claim 1, wherein a height H2 of each of the optical functional pillars in the optical functional layer satisfies 3 μm>H2>0.2 μm.
